(19) United States
(12) Patent Application Publication
(10) Pub. No.: US 2025/0207296 A1
(43) Pub. Date: Jun. 26, 2025

(54) GROUP III NITRIDE LAMINATE AND METHOD OF PRODUCING GROUP III NITRIDE LAMINATE

(71) Applicant: SUMITOMO CHEMICAL COMPANY, LIMITED, Tokyo (JP)

(72) Inventor: Taiki YAMAMOTO, Hitachi-shi (JP)

(73) Assignee: SUMITOMO CHEMICAL COMPANY, LIMITED, Tokyo (JP)

(21) Appl. No.: 19/000,118

(22) Filed: Dec. 23, 2024

(30) Foreign Application Priority Data
Dec. 26, 2023 (JP) 2023-219122

(51) Int. Cl. C30B 29/68; C30B 25/16; C30B 29/40; H10D 30/47; H10D 62/85

(52) U.S. Cl. CPC C30B 29/68; C30B 25/16; C30B 29/403; C30B 29/406; H10D 62/8503; H10D 30/471

(57) ABSTRACT

A group III nitride laminate, including: an underlying substrate; a first layer which is provided on the underlying substrate and contains aluminum nitride; and a second layer which is provided on the first layer and contains gallium nitride, wherein the thickness of the first layer is 11.0 nm or more, and in a region corresponding to a thickness of the first layer, an AlN abundance ratio, which is a ratio of the amount of the aluminum nitride to the total amount of the aluminum nitride and the gallium nitride is less than 78%.

### TECHNICAL FIELD

The present disclosure relates to a group III nitride laminate and a method of producing a group III nitride laminate.

### DESCRIPTION OF RELATED ART

A group III nitride-based high electron mobility transistor (HEMT) is widely used as a power amplifier for a cell phone base station (e.g., Patent Document 1). In a group III nitride-based HEMT, the power that can be input per element can be remarkably increased as compared with a Si-based device that has been used conventionally. As a result, the base station can be miniaturized, which greatly reduces the installation cost.

### PRIOR ART DOCUMENT

### Patent Document

[Patent Document 1] Japanese Patent Laid Open Publication No. 2006-286741

### SUMMARY OF THE INVENTION

### Problem to be solved by the Invention

A semiconductor element such as HEMT is produced from a group III nitride laminate. According to the investigations of the present inventors, surface defects may exist in a group III nitride laminate, and the surface defects may prevent desired device characteristics from being obtained in a semiconductor element.

An object of the present disclosure is to provide a technique for reducing surface defects in a group III nitride laminate.

### Means for Solving the Problem

In an aspect of the present disclosure,
there is provided a group III nitride laminate including:
   an underlying substrate;
   a first layer which is provided on the underlying substrate and contains aluminum nitride; and
   a second layer which is provided on the first layer and contains gallium nitride,
wherein the thickness of the first layer is 11.0 nm or more, and
in a region corresponding to a thickness of the first layer, an AlN abundance ratio, which is a ratio of the amount of the aluminum nitride to the total amount of the aluminum nitride and the gallium nitride is less than 78%.

In another aspect of the present disclosure,
there is provided a method of producing a group III nitride laminate, including:
forming a first layer containing aluminum nitride on an underlying substrate; and
forming a second layer containing gallium nitride on the first layer,
wherein in the formation of the first layer, the first layer is formed so that an AlN abundance ratio, which is a ratio of the amount of the aluminum nitride to the total amount of the aluminum nitride and the gallium nitride, in a region corresponding to a thickness of the first layer is less than 78%, while a thickness of the first layer is set to 11.0 nm or more.

### Advantage of the invention

According to the present disclosure, surface defects can be reduced in a group III nitride laminate.

### BRIEF DESCRIPTION OF THE DRAWINGS

FIG. 1 is a schematic cross-sectional diagram illustrating a group III nitride laminate according to a first embodiment of the present disclosure.

FIG. 2 is a partially enlarged cross-sectional diagram of a group III nitride laminate according to this embodiment.

FIG. 3 is a diagram for explaining the correlation between the AlN abundance ratio and the number of surface defects.

FIG. 4 is a diagram for explaining the correlation between a film thickness of a first layer containing aluminum nitride and the number of surface defects.

FIG. 5 is a diagram for explaining an average density of the surface defects.

FIG. 6 is a flow chart illustrating a method of producing a group III nitride laminate according to the first embodiment of the present disclosure.

FIG. 7 is a cross-sectional image of sample 1 observed by TEM.

### DETAILED DESCRIPTION OF THE INVENTION

### Knowledges Obtained by the Inventors

First, the knowledges obtained by the inventors will be described.

A group III nitride laminate (hereinafter also referred to simply as laminate) for producing a group III nitride-based semiconductor element is constituted by laminating, for example, a predetermined underlying substrate; a first layer which contains aluminum nitride (AlN) and functions as a nucleation layer; a second layer which contains gallium nitride (GaN) and functions as a channel layer; and a third layer which includes a barrier layer and/or a cap layer.

In the laminate, surface defects may occur due to a combination of factors such as surface conditions of the underlying substrate and crystal growth conditions. Surface defects are microscopic unevenness (growth pits) that appear on the surface of the laminate due to a combination of factors. For example, during crystal growth, surface defects may occur on the surface at locations where dislocations with large strain or locally dense dislocations exist. Furthermore, for example, surface defects may occur on the crystal surface due to the surface conditions of the underlying substrate, such as foreign matters adhering to the surface or surface roughness of the underlying substrate. For example, incorporation of impurities into the crystal during growth may cause surface defects on the crystal surface.

In order to reduce surface defects generated due to such a combination of factors, the present inventors have focused on the first layer, which is a base for crystal growth and functions as a nucleation layer. The nucleation layer is formed by three-dimensional growth, and its surface may be formed unevenly in some cases. The uneven structure of the nucleation layer changes, for example, in terms of density, shape, and roughness of the unevenness depending on the growth conditions. The present inventors adjusted the growth conditions and formed the nucleation layer, and found a high correlation between the occurrence of surface defects and an AlN abundance ratio described later or the thickness of the nucleation layer, the AlN abundance ratio being an index related to an uneven structure and the thickness.

The present inventors have found that surface defects in the laminate can be remarkably reduced by adjusting each of the AlN abundance ratio and the thickness of the nucleation layer within a predetermined range.

The present disclosure is based on the above knowledges found by the present inventors.

### Details of Embodiment of the Disclosure

Next, an embodiment of the present disclosure will be described below with reference to the drawings. The present disclosure is not limited to these illustrations, but intended to be indicated by claims and encompass all the changes which fall within the meaning and scope equivalent to claims.

### First Embodiment of the Disclosure

A first embodiment of the present disclosure will be described hereafter, with reference to drawings.

### (1) Group III Nitride Laminate

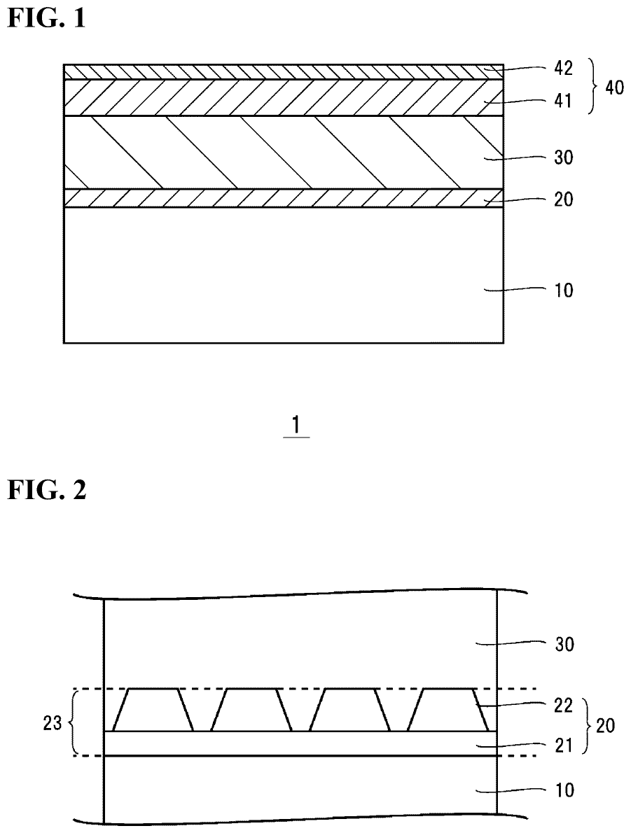

The group III nitride laminate according to this embodiment will be described with reference to FIG. 1. FIG. 1 is a schematic cross-sectional diagram illustrating a group III nitride laminate according to this embodiment.

Hereinafter, for example, in a crystal of the group III nitride semiconductor having a wurtzite structure, a <0001> axis is referred to as a “c-axis” and a (0001) plane is referred to as a “c-plane”.

As illustrated in FIG. 1, a group III nitride laminate 1 of this embodiment (laminate 1) is constituted to include, for example, an underlying substrate 10, a nucleation layer 20 as a first layer containing aluminum nitride (AlN), a channel layer 30 as a second layer containing gallium nitride (GaN), and a third layer 40 containing group III nitride represented by a composition formula: InₓAl_{y}Ga_{(1-x-y)}N (0≤x≤1, 0≤y≤1, x+y≤1). A case where the third layer 40 is constituted by a barrier layer 41 and a cap layer 42 will be described herein as an example. Each layer will be described below.

### Underlying Substrate

The underlying substrate 10 is composed of silicon carbide (SiC) or sapphire (Al₂O₃). Here, the underlying substrate 10 is, for example, a SiC substrate. The polytype of the SiC substrate as the underlying substrate 10 is, for example, 4H, 6H, or 3C, but is not limited thereto. The SiC substrate as the underlying substrate 10 is preferably semi-insulating.

The underlying substrate 10 has a main surface which serves as a base surface. In this embodiment, the crystal plane that has the low index and is closest to the base surface is, for example, the c-plane ((0001) plane, Si-plane).

The underlying substrate 10 preferably has a large area, for example, in order to improve productivity during production of a semiconductor element. Specifically, a diameter of the underlying substrate 10 is, for example, 2 inches (50 mm) or more, preferably 4 inches (100 mm) or more, and more preferably 6 inches (150 mm) or more.

The thickness of the underlying substrate 10 is not particularly limited, but depends on the diameter of the underlying substrate 10. Specifically, the thickness of the underlying substrate 10 having a diameter of 2 inches is 300 μm or more and 500 μm or less (typically 430 μm). For example, the thickness of the underlying substrate 10 having a diameter of 4 inches is 400 μm or more and 1000 μm or less (typically 500 μm). For example, the thickness of the underlying substrate 10 having a diameter of 6 inches is 400 μm or more and 1500 μm or less (typically 500 μm).

### First Layer

A nucleation layer 20 is provided as a first layer on the underlying substrate 10. The nucleation layer 20 contains AlN, and is constituted, for example, to generate crystal nuclei for growing the channel layer 30 as a second layer containing GaN described later. The nucleation layer 20 is formed, for example, by heteroepitaxially growing single crystals of AlN on the base surface of the underlying substrate 10.

As illustrated in FIG. 2, the nucleation layer 20 is configured by laminating an initial growth layer 21 provided on the underlying substrate 10 and a three-dimensional structure layer 22 provided thereon. FIG. 2 is a partially enlarged cross-sectional diagram of a group III nitride laminate according to this embodiment. On the surface of the nucleation layer 20, an uneven structure derived from the three-dimensional structure layer 22 is formed.

In the nucleation layer 20, the initial growth layer 21 serves as a base for growing the three-dimensional structure layer 22. The initial growth layer 21 is formed by growing AlN crystals at a first growth rate. As for the first growth rate, a condition that increases the wettability of the AlN crystal with respect to the underlying substrate 10 is preferred. By adopting such conditions, it is possible to grow AlN crystals so as to continuously cover the surface of the underlying substrate 10. As a result, the initial growth layer 21, although thin, can be formed so that there is less exposed area of the underlying substrate 10, preferably the entire substrate 10 is continuously covered with no exposed area.

The three-dimensional structure layer 22 is formed by three-dimensionally growing AlN crystals on the initial growth layer 21 at the second growth rate. As for the second growth rate, a condition that promotes the three-dimensional growth of the AlN crystals is preferred. It is preferable that the three-dimensional structure layer 22 is uniformly formed on the main surface of the initial growth layer 21. As described in detail below, it is preferable that the three-dimensional structure layer 22 is constituted so that the top surface of the apex of the uneven structure is a c-plane.

### Second Layer

On the nucleation layer 20, a channel layer 30 is provided as a second layer. The channel layer 30 is constituted, for example, to transport electrons during operation of a semiconductor element such as a HEMT. The channel layer 30 is formed, for example, by heteroepitaxially growing GaN single crystals on the main surface of the nucleation layer 20. The crystal plane that has the low index and is closest to the main surface of the channel layer 30 is, for example, the c-plane ((0001) plane, Ga-plane).

The thickness of the channel layer 30 is not particularly limited, but preferably 100 nm or more and less than 1 μm, for example. The channel layer 30 may be provided directly on the nucleation layer 20. Alternatively, for example, a known buffer layer may be provided on the nucleation layer 20, and the channel layer 30 may be provided above the nucleation layer 20 with the buffer layer intervening therebetween.

### Mixed Layer

In this embodiment, a channel layer 30 is formed on the uneven structure of the nucleation layer 20, so that the region corresponding to the thickness of the nucleation layer 20 becomes a mixed layer 23 constituted by the channel layer 30 embedded in the recessed portions on the surface of the nucleation layer 20. In the mixed layer 23, the amount of the channel layer 30 varies depending on, for example, the density, shape, and height of the protruding portions in the uneven structure, and the thickness of the nucleation layer 20. Therefore, in the mixed layer 23, the proportion of AlN and the proportion of GaN increase or decrease due to the differences in the uneven structure and the thickness of the nucleation layer 20. For example, in a case where the thickness of the nucleation layer 20 is constant, the proportion of GaN tends to increase and the proportion of AlN tends to decrease when the density of the protruding portions in the uneven structure decreases or when the cross-sectional shape of the protruding portion is triangular. Conversely, when the density of the protruding portions increases or the uneven structure becomes flat, the proportion of AlN tends to increase and the proportion of GaN tends to decrease. Furthermore, for example, with the nucleation layer 20 having the same uneven structure, the proportion of AlN in the mixed layer 23 tends to increase as the nucleation layer 20 becomes thicker. That is, in the mixed layer 23, the amount ratio (composition ratio) of AlN and GaN constituting the mixed layer 23 varies depending on the thickness and uneven structure of the nucleation layer 20. Therefore, the AlN abundance ratio, which is the ratio of the amount of AlN to the total amount of AlN and GaN in the mixed layer 23, is an index relating to the uneven structure and thickness of the nucleation layer 20.

As described above, according to the study by the present inventors, it has been found that the AlN abundance ratio in the mixed layer 23 and the thickness of the nucleation layer 20 are highly correlated with the occurrence of surface defects in the laminate 1, and that the surface defects can be remarkably reduced by setting each of them within a predetermined range. This point will be explained below.

First, the AlN abundance ratio will be described. The AlN abundance ratio can be calculated by measuring the amount of AlN and the amount of GaN in the mixed layer 23. Possible examples of the method of measuring these quantities include a method using a cross-sectional TEM capable of analyzing a microstructure, a method using an Atomic Force Microscope (AFM), and a method using spectroscopic ellipsometry. In this regard, the investigation by the present inventors has found that a method using spectroscopic ellipsometry is effective. The method using a cross-sectional TEM not only requires the sample to be destroyed to obtain a cross-section of the mixed layer 23, but also fails to obtain information in the direction perpendicular to the cross-sectional surface of the mixed layer 23, obtaining only localized information. The method using AFM not only provides local information alone, but also requires observation of the nucleation layer 20 before the formation of the channel layer 30, failing to measure a sample as a laminate 1 in some cases. In contrast, spectroscopic ellipsometry makes it possible to analyze the reflected polarized spectrum by modeling the mixed layer 23 using an effective medium approximation, and therefore the composition ratio can be obtained with higher accuracy. In addition, spectroscopic ellipsometry allows non-destructive and high-throughput detection of the laminate 1.

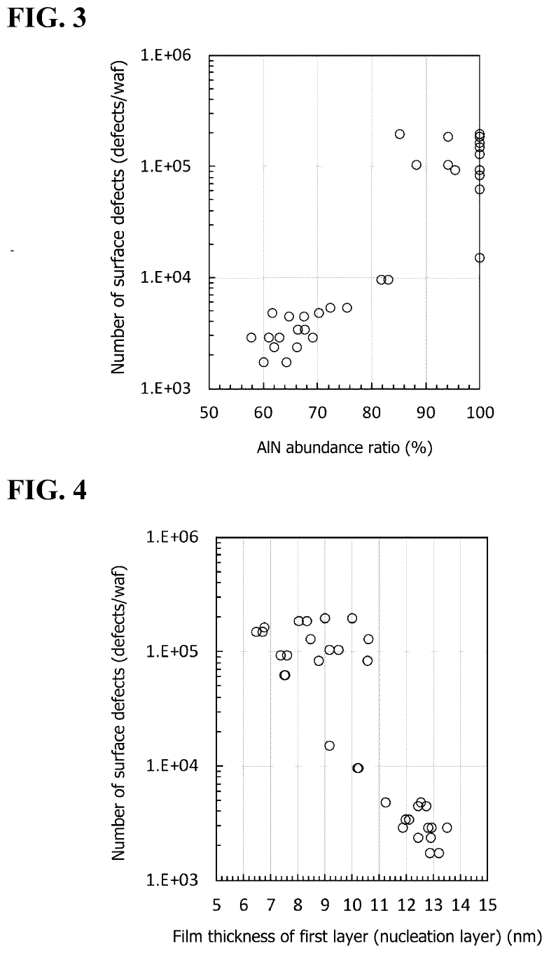

Next, the correlation between the AlN abundance ratio and the number of surface defects will be described with reference to FIG. 3. FIG. 3 is a diagram for explaining the correlation between the AlN abundance ratio and the number of surface defects. FIG. 3 illustrates the results of measuring the number of surface defects on the surface of the laminate 1 when the thickness of the nucleation layer 20 is adjusted in the range from 12 nm to 14 nm and the growth conditions are appropriately changed to vary the AlN abundance ratio. In FIG. 3, the horizontal axis indicates the AlN abundance ratio [%], and the vertical axis indicates the number of surface defects [defects/waf] in the laminate 1. The number of surface defects indicates the total number of surface defects per laminate 1.

As illustrated in FIG. 3, when the AlN abundance ratio is 100%, that is, when the surface of the nucleation layer 20 is flat with no unevenness formed thereon, it can be confirmed that many surface defects occur in the laminate 1. On the other hand, when the AlN abundance ratio becomes low and an uneven structure is introduced into the surface of the nucleation layer 20, surface defects tend to decrease. Particularly, it can be confirmed that when the AlN abundance ratio is less than 78%, the surface defects are remarkably reduced. In this case, it is presumed that the density, shape, etc. of the protruding portions in the uneven structure can be constituted so as to reduce surface defects when producing the laminate 1. From the viewpoint of more reliably reducing surface defects, the AlN abundance ratio is preferably 75% or less, and more preferably 70% or less.

The lower limit of the AlN abundance ratio is not particularly limited, but is preferably 47% or more. When the AlN abundance ratio is excessively low, the nucleation layer 20 cannot be formed continuously on the underlying substrate 10 in some cases. For example, the initial growth layer 21 cannot be formed to cover the underlying substrate 10 in some cases. As a result, the underlying substrate 10 may be exposed in some cases. When GaN is epitaxially grown on the exposed underlying substrate 10, the crystallinity of GaN itself cannot be maintained in some cases. In this regard, by forming the nucleation layer 20 so that the AlN abundance ratio is 47% or more, it is possible to continuously form the initial growth layer 21 on the underlying substrate 10 and form a three-dimensional structure layer 22 thereon, obtaining a nucleation layer 20 having an appropriate uneven structure and thickness that can reduce surface defects. From the viewpoint of more stably forming the nucleation layer 20 having an appropriate uneven structure and thickness, the AlN abundance ratio is preferably 56% or more.

Next, the correlation between the thickness of the nucleation layer 20 and the number of surface defects will be described with reference to FIG. 4. FIG. 4 is a diagram for explaining the correlation between a film thickness of the nucleation layer 20 containing aluminum nitride and the number of surface defects. FIG. 4 illustrates the results of measuring the number of surface defects on the surface of the laminate 1 when the AlN abundance ratio in the mixed layer 23 is adjusted within a range from 65% to 75% and the thickness of the nucleation layer 20 is appropriately changed. In FIG. 4, the horizontal axis indicates the thickness [nm] of the nucleation layer 20, and the vertical axis indicates the number of surface defects [defects/waf] in the laminate 1. The film thickness of the nucleation layer 20 is the thickness corresponding to the mixed layer 23 and indicates the maximum thickness of the nucleation layer 20.

As illustrated in FIG. 4, the thinner the nucleation layer 20 is, the more surface defects tend to occur. When the nucleation layer 20 is formed thin, for example, the initial growth layer 21 cannot be formed to continuously cover the underlying substrate 10, and the underlying substrate 10 may be exposed in some cases. Furthermore, for example, the three-dimensional growth of the three-dimensional structure layer 22 may be insufficient, failing to form a predetermined uneven structure in some cases, for example, resulting in low protruding portions or a low density of protruding portions. As a result, it is presumed that when growing the channel layer 30 and the third layer 40 described below, the influence of factors that cause surface defects becomes greater, resulting in increased surface defects. In this regard, the thicker the nucleation layer 20, the more likely it is that an appropriate uneven structure can be formed which can reduce surface defects while being continuously formed on the underlying substrate 10, and when the thickness of the nucleation layer 20 is 11 nm or more, the surface defects can be more remarkably reduced.

The upper limit of the thickness of the nucleation layer 20 is not particularly limited. Since the AlN abundance ratio tends to increase as the nucleation layer 20 becomes thicker, it is advisable to appropriately adjust the AlN abundance ratio within a range of less than 78%. When the nucleation layer 20 becomes excessively thick, the productivity of the laminate 1 decreases, and further high frequency characteristics and electrical characteristics of the semiconductor element tend to deteriorate. From the viewpoint of obtaining high productivity while maintaining high frequency characteristics and electrical characteristics, the thickness of the nucleation layer 20 is preferably 30 nm or less, more preferably 20 nm or less, and even more preferably 15 nm or less.

As described above, the surface defects in the laminate 1 can be reduced by setting each of the AlN abundance ratio in the mixed layer 23 and the thickness of the nucleation layer 20 within a predetermined range.

From the viewpoint of more stably adjusting the AlN abundance ratio within the predetermined range in the mixed layer 23, it is preferable that the three-dimensional structure layer 22 of the nucleation layer 20 is constituted so that the top surface of the apex of its uneven structure becomes a c-plane. According to the three-dimensional structure layer 22 having the c-plane, the cross-sectional shape of the protruding portion can be trapezoidal, as illustrated in FIG. 2. Moreover, the area of the surface on the channel layer 30 side can be made smaller than the area of the surface on the underlying substrate 10 side. By introducing a c-plane into the three-dimensional structure layer 22, the amount of the channel layer 30 embedded in the mixed layer 23 can be reduced compared to a case where the c-plane is not present and the protruding portions have acute angles. That is, the AlN abundance ratio can be increased. Moreover, the AlN abundance ratio can be adjusted by widening or narrowing the area of the c-plane. As a result, the AlN abundance ratio can be more stably adjusted within a predetermined range while the nucleation layer 20 is formed thin.

From the viewpoint of more stably adjusting the AlN abundance ratio within the predetermined range in the mixed layer 23, it is preferable that the thickness of the initial growth layer 21 in the nucleation layer 20 is made smaller than the thickness of the three-dimensional structure layer 22. This allows the AlN abundance ratio to be adjusted within the predetermined range while the thickness of the nucleation layer 20 is reduced. It is preferable that the initial growth layer 21 has a thickness at least sufficient to uniformly cover the entire surface so that the underlying substrate 10 is not exposed. The thickness of the three-dimensional structure layer 22 may be appropriately adjusted in accordance with the thickness of the initial growth layer 21 so that the AlN abundance ratio is within the predetermined range.

### Third Layer

On the channel layer 30, a barrier layer 41 and a cap layer 42 are provided as a third layer formed from group III nitride crystals represented by the composition formula: InₓAl_{y}Ga_{(1-x-y)}N (0≤x≤1, 0≤y≤1, x+y≤1).

The barrier layer 41 is provided on the channel layer 30. The barrier layer 41 is constituted to generate two-dimensional electron gas (2DEG) in the channel layer 30 and to spatially confine the 2DEG within the channel layer 30. The barrier layer 41 is formed, for example, by heteroepitaxially growing group III nitride crystals on the main surface of the channel layer 30. For example, the barrier layer 41 is constituted by group III nitride having a smaller electron affinity than that of the group III nitride crystals constituting the channel layer 30, such as AlGaN containing aluminum (Al) and gallium (Ga). The thickness of the barrier layer 41 is preferably 1 nm or more and 50 nm or less, for example.

The cap layer 42 is provided on the barrier layer 50. The cap layer 42 is interposed between the barrier layer 41 and an electrode provided thereon in order to improve the device characteristics (such as the controllability of the threshold voltage) of a semiconductor element such as a HEMT. The cap layer 42 is constituted by GaN, for example. The cap layer 42 is formed as needed and may be omitted.

### Surface Defect

In the laminate 1 of this embodiment, the nucleation layer 20 is constituted to have a predetermined AlN abundance ratio and thickness, the channel layer 30, barrier layer 41, and the like are formed sequentially on the nucleation layer 20. Therefore, the laminate 1 is constituted so that the occurrence of surface defects is suppressed and their density is reduced.

Surface defects are microscopic unevenness (growth pits) that are caused by a combination of factors such as crystal growth conditions and the surface condition of the underlying substrate and appear on the surface of the laminate 1, as described above. When the surface of the laminate 1 is irradiated with laser light and scanned, the presence of surface defects can be confirmed and detected according to the state of reflection and scattering of the irradiated light. The surface defects preferably have a size of 0.165 μm or more and 2.0 μm or less in a planar view. The surface defects having such a size are those generated by crystal growth and are substantially free of coarse foreign matters (e.g., external particles) attached to the crystal surface. The surface defects in the laminate 1 are those formed on the surface of the top layer of the laminate 1. In this embodiment, since the top layer of the laminate 1 is a cap layer 42, the surface defects in the laminate 1 are those formed on the surface of the cap layer 42.

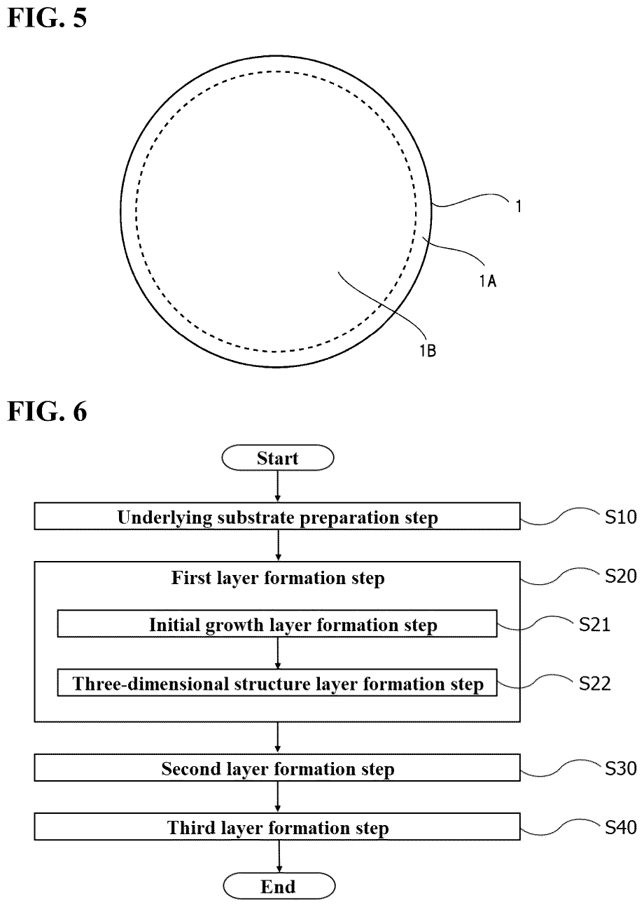

The average density of surface defects in the laminate 1 is preferably 500 defects/cm² or less, more preferably 100 defects/cm² or less, and even more preferably 25 defects/cm² or less. Here, the calculation of the average density of surface defects is explained with reference to FIG. 5. FIG. 5 is a diagram for explaining the average density of surface defects, and is a schematic diagram of the surface of the laminate 1 in a top view. As illustrated in FIG. 5, the average density of surface defects is the total number of surface defects present in an internal region 1B (the region surrounded by a dashed line in the figure) excluding a width of 5 mm from the outer rim on the surface 1A of the laminate 1, divided by the area of the internal region 1B, and indicates the number of surface defects per unit area.

### (3) Method of Producing Group III Nitride Laminate

Next, a method of producing a group III nitride laminate according to this embodiment will be described with reference to FIG. 6. FIG. 6 is a flow chart illustrating a method of producing a group III nitride laminate according to this embodiment.

The method of producing a group III nitride laminate according to this embodiment includes, for example, an underlying substrate preparation step S10, a first layer formation step S20, a second layer formation step S30, and a third layer formation step S40.

### S10: Underlying Substrate Preparation Step

First, an underlying substrate 10 is prepared. As the underlying substrate 10, for example, a polytype 6H semi-insulating SiC substrate is prepared.

### S20: First Layer Formation Step

Next, single crystals of AlN are heteroepitaxially grown as a first layer on a base surface of the underlying substrate 10 to form a nucleation layer 20. The nucleation layer 20 may be grown by, for example, a metalorganic vapor phase epitaxy (MOVPE) method.

As a group III (Al) source gas, for example, trimethylalminum (TMA) gas is used. As a N source gas, for example, NH₃ gas is used. These source gases may be mixed and supplied with a carrier gas including hydrogen (H₂) gas, nitrogen (N₂) gas, or a mixed gas thereof.

According to this embodiment, in the first layer formation step S20, first, an initial growth layer 21 is formed, and a three-dimensional structure layer 22 is then formed. The following is a specific explanation.

### Initial Growth Layer Formation Step S21

First, the initial growth layer 21 is formed by growing AlN crystals at a first growth rate. Here, as for the first growth rate, a condition that allows the AlN crystals to cover the underlying substrate 10 with high wettability is preferred. This allows the initial growth layer 21 to be formed so as to cover the entire base surface of the underlying substrate 10 continuously. As a result, the initial growth layer 21 can be formed thin without exposing the underlying substrate 10.

The first growth rate is not particularly limited, but preferably 50 nm/h or more and 500 nm/h or less from the viewpoint of growing the AlN crystals with high wettability with respect to the underlying substrate 10. The first growth rate can be changed by appropriately adjusting the supply amount of a group III source gas such as TMA.

Regarding the growth conditions for forming the initial growth layer 21, conditions except for the growth rate, such as the growth temperature, the V/III ratio, and the growth pressure, may be appropriately adjusted in accordance with the growth rate. The term “V/III ratio” used herein means a ratio of a supply amount (partial pressure) of a group V (N) source gas to a supply amount (partial pressure) of a group III (Al) source gas.

Specifically, the crystal growth conditions except for the growth rate are set as follows, for example.
Growth temperature: 1200° C. or more and 1390° C. or less
V/III ratio: 5000 or more and 25000 or less
Growth pressure: 0.059 atm or more and 0.197 atm or less

### Three-Dimensional Structure Layer Formation Step S22

Subsequently, AlN crystals are grown on the main surface of the initial growth layer 21 at a second growth rate to form a three-dimensional structure layer 22. Thus, the nucleation layer 20 is formed.

As for the second growth rate, a condition that promotes the three-dimensional growth of the AlN crystals is preferred. Further, the condition that allows the three-dimensional structure layer 22 to be uniformly formed on the main surface of the initial growth layer 21 is preferred. This allows the AlN abundance ratio to be adjusted within the predetermined range in the mixed layer 23 when the channel layer 30 is formed on the nucleation layer 20. The condition that allows the top surface of the apex of the uneven structure of the three-dimensional structure layer 22 to be a c-plane, that is, the cross-sectional shape of the protruding portions to be trapezoidal is preferred. This allows the AlN abundance ratio to be more reliably adjusted within the predetermined range.

As with the first growth rate, the second growth rate can be changed by adjusting the supply amount of the group III source gas as appropriate. The second growth rate is not particularly limited, but is preferably 80 nm/h or more and 700 nm/h or less, from the viewpoint of three-dimensionally growing AlN crystals. As with the first growth rate, the second growth rate can be changed by appropriately adjusting the supply amount of TMA.

Each of the first growth rate and the second growth rate may be adjusted appropriately from the above ranges. From the viewpoint of adjusting the AlN abundance ratio in the mixed layer 23 within the predetermined range when the channel layer 30 is formed on the nucleation layer 20 in the second layer formation step S30 described below, the second growth rate may be the same as the first growth rate, or the second growth rate may be greater than the first growth rate. In other words, the second growth rate may be equal to or greater than the first growth rate. This allows the AlN crystals to grow with high wettability in the initial growth layer formation step S21, while the AlN crystals are grown in a more three-dimensional manner in the three-dimensional structure layer formation step S22, thereby forming a nucleation layer 20 having the desired thickness and uneven structure. As a result, the AlN abundance ratio can be adjusted within the predetermined range.

The second growth rate may be constant or may be increased continuously during the formation of the three-dimensional structure layer 22. When the second growth rate is continuously increased, the three-dimensional growth of the AlN crystals can be further promoted, a three-dimensional structure layer 22 having a desired uneven structure can be formed, and the AlN abundance ratio can be adjusted within a predetermined range. The increase ratio of the second growth rate is preferably set so that v2/v1 is more than 1 and 2 or less where v1 is the growth rate at the time of growth initiation of the three-dimensional structure layer 22 and v2 is the growth rate at the time of growth completion, for example. By increasing the second growth rate at this increase ratio, the desired uneven structure can be stably formed in the three-dimensional structure layer 22.

Regarding the crystal growth conditions for forming the three-dimensional structure layer 22, conditions except for the growth rate, such as the growth temperature, the V/III ratio, and the growth pressure, may be appropriately adjusted in accordance with the growth rate.

Specifically, the crystal growth conditions except for the growth rate are set as follows, for example:
Growth temperature: 1200° C. or more and 1390° C. or less
V/III ratio: 5000 or more and 25000 or less
Growth pressure: 0.059 atm or more and 0.197 atm or less

### S30: Second Layer Formation Step

Next, a channel layer 30 composed of GaN single crystals is heteroepitaxially grown as a second layer on the main surface of the nucleation layer 20. The growth of the channel layer 30 may be performed, for example, by the MOVPE method, similarly to the formation of the nucleation layer 20.

As the group III (Ga) source gas, for example, trimethylgallium (Ga(CH₃)₃, TMG) gas is used. As a N source gas, for example, NH₃ gas is used. These source gases may be mixed and supplied with a carrier gas including hydrogen (H₂) gas, nitrogen (N₂) gas, or a mixed gas thereof.

As the crystal growth conditions for the channel layer 30, for example, at least any one of growth temperature, growth rate, and growth pressure may be appropriately controlled so that GaN crystals can be grown three-dimensionally.

Specifically, the crystal growth conditions may be set as follows, for example.
Growth temperature: 1100° C. or more and 1300° C. or less
Growth rate: 1000 nm/h or more and 3000 nm/h or less
V/III ratio: 1000 or more and 3000 or less
Growth pressure: 0.098 atm or more and 0.296 atm or less

### S40: Third Layer Formation Step

Next, single crystals of a group III nitride represented by the composition formula: InₓAl_{y}Ga_{(1-x-y)}N (0≤x≤1, 0≤y≤1, x+y≤1) are heteroepitaxially grown on the main surface of the channel layer 30 to form a third layer 40 including a barrier layer 31 and a cap layer 42. In this embodiment, for example, single crystals of AlN, AlGaN, InAlN, or AlInGaN are grown first to form a barrier layer 41. Subsequently, for example, single crystals of GaN are grown on the barrier layer 41 to form a cap layer 42.

The barrier layer 41 and the cap layer 42 may be grown by the MOVPE method, for example, similarly to the formation of the nucleation layer 20 and the like. Trimethylalminum (Al(CH₃)₃, TMA) gas is used as an Al source gas, for example. Trimethylindium (In(CH₃)₃, TMI) gas is used as an In source gas, for example. For other gases, the same gas as in the second layer formation step S30 is used.

Furthermore, the thickness of the barrier layer 41 may be 5 nm or more and 50 nm or less, for example. The thickness of the cap layer 42 may be 1 nm or more and 10 nm or less, for example.

As described above, the laminate 1 of this embodiment can be produced.

### (4) Effect Obtained by this Embodiment

According to this embodiment, one or more of the following effects can be obtained.
(a) The laminate 1 of this embodiment is constituted so that a nucleation layer 20 which is a first layer containing AlN, a channel layer 30 which is a second layer containing GaN, and a third layer 40 are laminated on an underlying substrate 10, and the AlN abundance ratio in a mixed layer 23 which corresponds to the thickness of the nucleation layer 20 is less than 78%, and the thickness of the nucleation layer 20 is 11 nm or more. With the AlN abundance ratio of less than 78%, the uneven structure of the nucleation layer 20 has protruding portions of a predetermined height at an appropriate density. Moreover, since the nucleation layer 20 has a predetermined thickness, when nitride semiconductor crystals are grown on the underlying substrate 10, surface defects that appear on the crystal surface can be remarkably reduced. This is presumably because the predetermined nucleation layer 20 reduces the effects of factors that cause surface defects, such as dislocations in the crystal, the surface condition of the underlying substrate 10, or the impurity incorporated into the crystal. In fact, it has been confirmed that the surface defects can be remarkably reduced by setting the AlN abundance ratio to less than 78% as illustrated in FIG. 3, and the surface defects can also be remarkably reduced by setting the thickness of the nucleation layer 20 to 11 nm or more as illustrated in FIG. 4. As described above, a laminate 1 with reduced surface defects is obtained.
(b) On the surface of the third layer 40 of the laminate 1, it is preferable that the average density of surface defects having a size of 0.165 μm or more and 2.0 μm or less is 500 defects/cm² or less. With such a laminate 1, when a semiconductor element such as a HEMT is produced, high device characteristics can be achieved.
(c) The nucleation layer 20 is preferably constituted so that it includes an initial growth layer 21 provided on the underlying substrate 10 and a three-dimensional structure layer 22 provided on the initial growth layer 21 and a top surface of an apex of an uneven structure of the three-dimensional structure layer 22 is a c-plane. By introducing a c-plane into the three-dimensional structure layer 22, the cross-sectional shape of the protruding portion can be made trapezoidal. As a result, the AlN abundance ratio can be increased while the nucleation layer 20 is formed thin, and the AlN abundance ratio can be more stably adjusted within a predetermined range. Namely, the effect of the above-mentioned (a) can be more stably obtained.
(d) The initial growth layer 21 is preferably provided so as to continuously cover the entire surface of the underlying substrate 10. This makes it possible to prevent the underlying substrate 10 from being exposed, so that GaN single crystals can be grown on the nucleation layer 20 and the channel layer 30 can be formed.
(e) The thickness of the nucleation layer 20 is preferably 30 nm or less. By forming the nucleation layer 20 thin to a predetermined thickness, the productivity of the laminate 1 can be improved, and the high frequency characteristics and electrical characteristics can be maintained at a high level in the semiconductor element produced from the laminate 1.
(f) In the mixed layer 23, the AlN abundance ratio is preferably 47% or more. Accordingly, the effect of the above-mentioned (e) can be more stably obtained.

### Other Embodiments

As described above, explanations have been given specifically for the embodiments of the present disclosure. However, the present disclosure is not limited thereto, and can be variously modified in a range not departing from the gist of the disclosure.

In the above-mentioned embodiment, a case where the third layer 40 which includes a barrier layer 41 and a cap layer 42 is formed on the channel layer 30 has been described, but the present disclosure is not limited thereto. For example, the third layer 40 may be constituted to include a barrier layer 41 without the cap layer 42. Alternatively, for example, the third layer 40 may be constituted such that an AlN layer is interposed between the barrier layer 41 and the channel layer 30. Alternatively, for example, the third layer 40 may be constituted such that an InGaN layer or an AlGaN layer is interposed within the channel layer 30.

In the above-mentioned embodiment, a case is described where the nucleation layer 20 and the channel layer 30 are grown by the MOVPE method. However, either one or both of them may be grown by, for example, the hydride vapor phase epitaxy (HVPE) method.

### EXAMPLES

Next, examples according to the present disclosure will be described. These examples are illustrative of the present disclosure. The present disclosure is not limited to these examples.

In the present examples, a group III nitride laminate was produced, and the average density of surface defects appeared on the surface was evaluated. The following is a specific explanation.

### (1) Preparation of Group III Nitride Laminate

First, a SiC substrate was prepared as an underlying substrate. Subsequently, the SiC substrate was introduced into a treatment vessel of an MOVPE apparatus. In the treatment vessel, AlN crystals were grown on the SiC substrate to form a nucleation layer as a first layer including an initial growth layer and a three-dimensional structure layer. Subsequently, GaN crystals were grown on the nucleation layer to form a channel layer as a second layer. Subsequently, a third layer including a barrier layer and a cap layer was formed on the channel layer to produce a laminate. The present example appropriately changed the growth rate and heating temperature among the growth conditions of the first layer as listed in Table 1 below to produce laminates of the samples 1 to 8. The first growth rate and the second growth rate were adjusted to the values listed in Table 1 by appropriately changing the supply amount of the group III source gas in accordance with the heating temperature.

TABLE 1

| | | | Sample | | | | | | | |
|---|---|---|---|---|---|---|---|---|---|---|
| | | | 1 | 2 | 3 | 4 | 5 | 6 | 7 | 8 |
| First | Growth conditions for | First growth rate [nm/h] | 200 | 200 | 200 | 200 | 200 | 200 | 200 | 200 |
| layer | initial growth layer | Heating temperature [° C.] | 1350 | 1300 | 1300 | 1250 | 1300 | 1300 | 1200 | 1200 |
| | Growth conditions for | Second growth rate [nm/b] | 350 | 300 | 250 | 200 | 200 | 200 | 300 | 200 |
| | three-dimensional | Heating temperature [° C.] | 1350 | 1300 | 1300 | 1250 | 1300 | 1300 | 1200 | 1200 |
| | structure layer | | | | | | | | | |

| | | | | | | | | | |
|---|---|---|---|---|---|---|---|---|---|
| Evaluation | Thickness of nucleation layer | 12.5 | 12.4 | 12.0 | 12.0 | 11.0 | 10.4 | 11.0 | 10.6 |
| | (AIN layer) [nm] | | | | | | | | |
| | AIN abundance ratio [%] | 47.1 | 66.1 | 67.8 | 77.9 | 74.5 | 75.8 | 80.6 | 83.3 |
| | Average density of surface | 18.4 | 11.2 | 15.2 | 17.0 | 21.6 | 587.8 | 1064.1 | 773.3 |
| | defects [defects/cm²] | | | | | | | | |

The details of the SiC substrate and the growth conditions of each layer are as follows.

### Underlying Substrate

Material: SiC (semi-insulating)
Diameter: 6 inches
Thickness: 500 μm
Crystal plane having the low index and being closest to base surface: c-plane (without pattern-processing on base surface)
Polytype: 6H

### Growth Condition for Initial Growth Layer

Material: AlN
Growth method: MOVPE method
V/III ratio: 5000 to 25000
Growth pressure: 0.059 atm to 0.098 atm

### Growth Condition for Three-Dimensional Structure

Material: AlN
Growth method: MOVPE method
V/III ratio: 5000 to 25000
Growth pressure: 0.059 atm to 0.098 atm

### Growth Condition for Channel Layer

Material: GaN
Growth method: MOVPE method
Growth temperature: 1100° C. to 1200° C.
V/III ratio: 1000 to 3000
Growth pressure: 0.098 atm to 0.197 atm
Thickness: 400 nm

### Growth Condition for Barrier Layer

Material: AlGaN
Growth method: MOVPE method
Growth temperature: 1100° C. to 1200° C.
Growth pressure: 0.098 atm to 0.197 atm
Thickness: 20 nm

### Cap Layer

Material: GaN
Growth method: MOVPE method
Thickness: 2 nm

### (2) Evaluation

For the samples 1 to 8 produced, the thickness of the nucleation layer and the AlN abundance ratio in the region (mixed layer) corresponding to the thickness of the nucleation layer were measured by spectroscopic ellipsometry. In addition, surface defects in the laminate were detected, and the average density was calculated. The following is a specific explanation.

### Thickness of Nucleation Layer and AlN Abundance Ratio

The thickness of the nucleation layer and the AlN abundance ratio were measured using a rotating compensator type spectroscopic ellipsometer (“M2000UI” manufactured by J. A. Woollam). Specifically, first, the surface of the laminate is irradiated with light (spot diameter: approximately 300 μm) at an incident angle of 70°, and the reflected light from the surface of the laminate is measured. Subsequently, the amount of change in polarized light between the incident light and the reflected light was obtained for each wavelength from the measurement data of the reflected light, and a polarized spectrum was obtained for the wavelength range from 245 nm to 1690 nm. Here, as the amounts of change in polarized light, the spectral phase difference between s-polarized light and p-polarized light and the spectral reflection amplitude ratio angle were obtained. Subsequently, curve fitting was performed on the polarized spectrum using predetermined fitting parameters based on a predetermined analytical model. In this case, as the analytical model, a laminated structure including SiC, a mixed layer (a mixture of AlN and GaN), GaN, AlGaN and GaN was adopted. For the mixed layer, an optical model of an effective medium approximation using Bruggeman equation was employed. Then, curve fitting was performed to minimize the mean square error (MSE) between the measured polarized spectrum and the theoretical value in the model. At this time, the thickness of each layer constituting the laminate, the AlN abundance ratio in the mixed layer, and the Al composition ratio and roughness in the AlGaN layer were selected as fitting parameters. Thus, the thickness and composition of each layer constituting the laminate were determined. The composition of the mixed layer indicates the mixture ratio of AlN and GaN, and corresponds to the AlN abundance ratio.

### Average Density of Surface Defects

For the produced samples 1 to 8, surface defects in the laminate were detected and the average density was evaluated. Specifically, the entire surface of the laminate was irradiated with a laser light using a wafer surface inspection apparatus (“YPI-MX-θ” manufactured by YGK CORPORATION), and surface defects were detected based on the state of reflection and scattering of the laser light. In the present example, surface defects were detected which have a size of 0.165 μm or more and 2.0 um or less in a surface view. At this time, when detecting surface defects, wavelength of the laser light was set to 375 nm, and a photomultiplier was employed as a detector. A total number of surface defects in an internal region of the surface of the laminate, excluding a 5 mm width area from the outer edge on the surface was determined, and divided by the area of the internal region to calculate the average density of surface defects. The surface defects were detected in an environment where the external particle count was less than 1.0 particles/cm³.

### (3) Evaluation Result

The results of the above evaluation are summarized in Table 1.

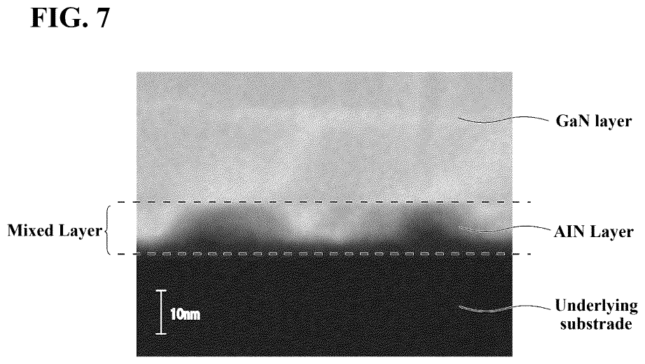

Observation of the cross-section of the sample 1 confirmed that the sample 1 was in the state illustrated in FIG. 7. FIG. 7 is a cross-sectional image of the sample 1 observed by TEM. In FIG. 7, an AlN layer which is a nucleation layer and a GaN layer which is a channel layer are formed on a SiC substrate which is an underlying substrate. It is confirmed that an uneven structure is formed on the surface of the AlN layer, and the region corresponding to the thickness of the AlN layer is a mixed layer in which AlN and GaN are mixed. It is also confirmed that the cross-sectional shape of the protruding portion of the uneven structure is trapezoidal, and its apex is a c-plane. It is also confirmed that the initial growth layer constituting the AlN layer is formed so as to continuously cover the entire main surface of the underlying substrate, and that its thickness is thinner than that of the three-dimensional structure layer. It is confirmed that in the samples 2 to 5, an uneven structure similar to that of the sample 1 is formed.

On the other hand, in the sample 1, it is confirmed that the thickness of the nucleation layer (AlN layer) is 12.5 nm, which is not less than 11 nm, and the AlN abundance ratio in the mixed layer is 47.1%, which is less than 78%, as shown in Table 1. In addition, it is confirmed that the average density of surface defects on the surface of the sample 1 is sufficiently low, as low as 18.4 defects/cm².

The reasons for the reduction of surface defects in the sample 1 is considered to be as follows. As illustrated in FIG. 7, it is confirmed that the AlN layer of the sample 1 has an AlN abundance ratio in the mixed layer of less than 78%, and therefore has an uneven structure in which protruding portions of a predetermined height are distributed at an appropriate density, and is constituted to be thin in thickness. It is presumed that such an AlN layer can suppress the effects of factors that cause surface defects, such as dislocations, the surface condition of the underlying substrate, and incorporation of impurities, when growing nitride semiconductor crystals on the AlN layer, thereby reducing the surface defects that appear on the crystal surface.

Furthermore, as illustrated in FIG. 7, it is confirmed that by introducing a c-plane into the top surface of the apex of the protruding structure of the AlN layer, the cross-sectional shape of the protruding portion can be made trapezoidal, and the AlN abundance ratio can be adjusted to be high while forming the AlN layer thin.

For the samples 2 to 5, as with the sample 1, it is confirmed that the surface defects can be reduced by setting the thickness of the AlN layer to 11 nm or more and the AlN abundance ratio to less than 78%.

On the other hand, for the sample 6, although the AlN layer was formed so that the AlN abundance ratio was less than 78%, the thickness of the AlN layer was less than 11 nm, and the average density of surface defects was found to exceed 500 defects/cm². The reason for this is presumably that the AlN layer is formed too thin to continuously form an initial growth layer or that protruding portions in the three-dimensional structure layer cannot be formed with an appropriate height or at an appropriate density, which makes it impossible to reduce the effects of factors that cause surface defects.

In the sample 7, the AlN layer was formed to a thickness of 11 nm or more, and the AlN abundance ratio was 80.6%, which is not less than 78%, and the average density was confirmed to be more than 500 defects/cm². The reason for the high average density is presumably due to high AlN abundance ratio and less GaN embedded in the mixed layer, which makes it impossible to form an uneven structure capable of suppressing surface defects, for example, excessively high density of protruding portions or low protruding portions.

In the sample 8, since the thickness of the AlN layer was less than 11 nm and the AlN abundance ratio was 78% or more, the average density was found to be more than 500 defects/cm². The reason for the high average density is presumably due to the existence of locally thin areas in the AlN layer or inability to form the predetermined uneven structure.

### Preferable Aspects of the Invention

Preferable aspects of the present disclosure will be supplementarily described hereafter.

### Supplementary Description 1

A group III nitride laminate, including:
an underlying substrate;
a first layer which is provided on the underlying substrate and contains aluminum nitride; and
a second layer which is provided on the first layer and contains gallium nitride,
wherein the thickness of the first layer is 11.0 nm or more, and
in a region corresponding to a thickness of the first layer, an AlN abundance ratio, which is a ratio of the amount of the aluminum nitride to the total amount of the aluminum nitride and the gallium nitride is less than 78%.

### Supplementary Description 2

The group III nitride laminate according to the supplementary description 1,
wherein an average density of surface defects having a size of 0.165 μm or more and 2.0 μm or less on the surface of the second layer is 500 defects/cm² or less.

### Supplementary Description 3

The group III nitride laminate according to the supplementary description 1 or 2,
wherein the group III nitride laminate further includes a third layer which is provided on the second layer and contains a group III nitride represented by a composition formula: InₓAl_{y}Ga_{(1-x-y)}N (0≤x≤1, 0≤y≤1, x+y≤1), and
an average density of surface defects having a size of 0.165 μm or more and 2.0 μm or less on the surface of the third layer is 500 defects/cm² or less.

### Supplementary Description 4

The group III nitride laminate according to any one of the supplementary descriptions 1 to 3,
wherein the first layer is constituted to include an initial growth layer which is provided so as to continuously cover a surface of the underlying substrate, and a three-dimensional structure layer which is provided on the initial growth layer and has an uneven structure on its surface, and
a top surface of an apex of the uneven structure is a c-plane.

### Supplementary Description 5

The group III nitride laminate according to any one of the supplementary descriptions 1 to 4,
wherein a thickness of the first layer is 30 nm or less.

### Supplementary Description 6

The group III nitride laminate according to any one of the supplementary descriptions 1 to 5,
wherein the AlN abundance ratio is 47% or more.

### Supplementary Description 7

The group III nitride laminate according to any one of the supplementary descriptions 1 to 6,
wherein a thickness of the initial growth layer is smaller than a thickness of the three-dimensional structure layer.

### Supplementary Description 8

A method of producing a group III nitride laminate, including:
forming a first layer containing aluminum nitride on an underlying substrate; and
forming a second layer containing gallium nitride on the first layer,
wherein in the formation of the first layer, the first layer is formed so that an AlN abundance ratio, which is a ratio of the amount of the aluminum nitride to the total amount of the aluminum nitride and the gallium nitride, in a region corresponding to a thickness of the first layer is less than 78%, while a thickness of the first layer is set to 11.0 nm or more.

### Supplementary Description 9

The method of producing a group III nitride laminate according to the supplementary description 8,
wherein the formation of the first layer includes:
   growing crystals containing aluminum nitride so as to continuously cover a surface of the underlying substrate to form an initial growth layer, and
   three-dimensionally growing crystals containing aluminum nitride on the first initial growth layer to form a three-dimensional structure layer having an uneven structure on its surface, and
in the formation of the three-dimensional structure layer, the crystals are grown under conditions to form a c-plane on a top surface of an apex of the uneven structure.

### Supplementary Description 10

The method of producing a group III nitride laminate according to the supplementary description 9,
wherein in the formation of the three-dimensional structure layer, the crystals containing aluminum nitride are grown while a second growth rate is continuously increased.

### Supplementary Description 11

The method of producing a group III nitride laminate according to the supplementary description 9 or 10,
wherein in the formation of the three-dimensional structure layer, the second growth rate is continuously increased so that v2/v1 is more than 1 and 2 or less, where v1 is a growth rate at the time of growth initiation and v2 is a growth rate at the time of growth completion.

### Supplementary Description 12

The method of producing a group III nitride laminate according to any one of the supplementary descriptions 9 to 11,
wherein in the formation of the first layer,
a first growth rate is set to 50 nm/h or more and 500 nm/h or less, and
the second growth rate is set to 80 nm/h or more and 700 nm/h or less.

### DESCRIPTION OF SIGNS AND NUMERALS

1 Group III nitride laminate (laminate)
2 Semiconductor element
10 Underlying substrate
20 Nucleation layer
21 Initial growth layer
22 Three-dimensional structure layer
23 Mixed layer
30 Channel layer
40 Third layer
41 Barrier layer
42 Cap layer

1. A group III nitride laminate, comprising:
an underlying substrate;
a first layer which is provided on the underlying substrate and contains aluminum nitride; and
a second layer which is provided on the first layer and contains gallium nitride,
wherein the thickness of the first layer is 11.0 nm or more, and
in a region corresponding to a thickness of the first layer, an AlN abundance ratio, which is a ratio of the amount of the aluminum nitride to the total amount of the aluminum nitride and the gallium nitride is less than 78%.

2. The group III nitride laminate according to claim 1,
wherein an average density of surface defects having a size of 0.165 μm or more and 2.0 μm or less on the surface of the second layer is 500 defects/cm² or less.

3. The group III nitride laminate according to claim 1,
wherein the group III nitride laminate further comprises a third layer which is provided on the second layer and contains a group III nitride represented by a composition formula: InₓAl_{y}Ga_{(1-x-y)}N (0≤x≤1, 0≤y≤1, x+y≤1), and an average density of surface defects having a size of 0.165 μm or more and 2.0 μm or less on the surface of the third layer is 500 defects/cm² or less.

4. The group III nitride laminate according to claim 1,
wherein the first layer is constituted to include an initial growth layer which is provided so as to continuously cover a surface of the underlying substrate, and a three-dimensional structure layer which is provided on the initial growth layer and has an uneven structure on its surface, and
a top surface of an apex of the uneven structure is a c-plane.

5. The group III nitride laminate according to claim 1,
wherein a thickness of the first layer is 30 nm or less.

6. The group III nitride laminate according to claim 1,
wherein the AlN abundance ratio is 47% or more.

7. The group III nitride laminate according to claim 4,
wherein a thickness of the initial growth layer is smaller than a thickness of the three-dimensional structure layer.

8. A method of producing a group III nitride laminate, comprising:
forming a first layer containing aluminum nitride on an underlying substrate; and
forming a second layer containing gallium nitride on the first layer,
wherein in the formation of the first layer, the first layer is formed so that an AlN abundance ratio, which is a ratio of the amount of the aluminum nitride to the total amount of the aluminum nitride and the gallium nitride, in a region corresponding to a thickness of the first layer is less than 78%, while a thickness of the first layer is set to 11.0 nm or more.

9. The method of producing a group III nitride laminate according to claim 8,
wherein the formation of the first layer comprises:
growing crystals containing aluminum nitride so as to continuously cover a surface of the underlying substrate to form an initial growth layer, and
three-dimensionally growing crystals containing aluminum nitride on the first initial growth layer to form a three-dimensional structure layer having an uneven structure on its surface, and
in the formation of the three-dimensional structure layer, the crystals are grown under conditions to form a c-plane on a top surface of an apex of the uneven structure.

10. The method of producing a group III nitride laminate according to claim 9,
wherein in the formation of the three-dimensional structure layer, the crystals containing aluminum nitride are grown while a second growth rate is continuously increased.

11. The method of producing a group III nitride laminate according to claim 9,
wherein in the formation of the three-dimensional structure layer, the second growth rate is continuously increased so that v2/v1 is more than 1 and 2 or less, where v1 is a growth rate at the time of growth initiation and v2 is a growth rate at the time of growth completion.

12. The method of producing a group III nitride laminate according to claim 9,
wherein in the formation of the first layer,
a first growth rate is set to 50 nm/h or more and 500 nm/h or less, and
the second growth rate is set to 80 nm/h or more and 700 nm/h or less.
